(19) United States
(12) Patent Application Publication
(10) Pub. No.: US 2011/0277808 A1
(43) Pub. Date: Nov. 17, 2011

(54) MEMS SOLAR CELL DEVICE AND ARRAY

(75) Inventors: Andrei J. Pavlov, Naantali (FI); Yelena V. Pavlova, Naantali (FI)

(73) Assignee: ScanNanoTek Oy, Turku (FI)

(21) Appl. No.: 13/053,634

(22) Filed: Mar. 22, 2011

Related U.S. Application Data
(60) Provisional application No. 61/316,248, filed on Mar. 22, 2010.

(51) Int. Cl. H01L 31/042; H01L 31/06

(52) U.S. Cl. 136/244; 136/255

(57) ABSTRACT

A microelectromechanical system (MEMS) solar cell device. The MEMS solar cell device includes a substrate, a sensing membrane exposed to light radiation being spaced from the substrate, a collector electrode disposed between the substrate and the sensing membrane, and a cavity defined between the sensing membrane and the collector electrode. The collector electrode collects charge carriers generated by light radiation on the sensing membrane within the cavity. A solar module or panel may be provided including a plurality of the cells arranged in an array on a substrate.

### CROSS-REFERENCE TO RELATED APPLICATIONS

This application claims priority under 35 U.S.C. §119(e) to U.S. Provisional Application No. 61/316,248 filed Mar. 22, 2010, the entire contents of which are hereby incorporated by reference.

### BACKGROUND

1. Field of Invention

The invention relates generally to Microelectromechanical systems (MEMS) and, more particularly, to MEMS solar cell devices.

2. Discussion of Related Art

Microelectromechanical systems (MEMS) is the technology of very small mechanical devices driven by electricity. Advances in fabrication technology have merged at the nano-scale into nanoelectromechanical systems (NEMS) and nanotechnology. MEMS are also referred to as micromachines as well as Micro Systems Technology (MST). As herein used, MEMS refers to devices integrating electrical and mechanical functionality on the micro- and nano-scale. MEMS typically integrate transistor-like nanoelectronics with mechanical actuators, pumps, or motors, and may thereby form physical, biological, and chemical sensors. The dimensions in the nanometer range lead to low mass and high mechanical resonance frequencies.

One type of MEMS devices comprise microstructures that are usually separated from other control elements, for example control electrodes, by narrow air gaps. The MEMS devices have movable structures that can move over the space provided by the gap. Usually, this movement is used to make a contact with an electrode, such as in a MEMS switch. Variation of the width of the gap can be used to change electrical characteristics of the device, such as a variable capacitor. In many applications, the MEMS structure is used as a sensitive element and the movement of the microstructure is used to detect an external effect such as pressure, acceleration, etc. In many applications, performance of the MEMS structure is limited by the size of the gap. Larger gaps require greater forces to enable the MEMS structure to move. Accordingly, the sensitivity of the MEMS structure is lower for larger gaps and higher power is needed to control it. For example, electrical voltages that are needed for the operation of MEMS devices is relatively high, i.e., of the order of a few tens of Volts. To improve performance of MEMS devices, significantly smaller gaps are needed. The smaller gaps can improve sensitivity and allow for lower power operation of the devices.

A solar cell (also called photovoltaic cell or photoelectric cell) is a solid state device that converts the energy of sunlight directly into electricity by the photovoltaic effect. Assemblies of cells are used to make solar modules, also known as solar panels. The energy generated from these solar modules, referred to as solar power, is an example of solar energy. Solar cells are generally solid state devices. In the case of a p-n junction solar cell, illuminating the material creates an electric current as excited electrons and the remaining holes are swept in different directions by the built-in electric field of the depletion region.

Semiconductor solar cells devices based on use of the p-n junction (see, e.g., U.S. Pat. No. 2,780,765 to Chapin, incorporated herein by reference) may be prepared, for example, on a crystalline silicon. Usually, one p-n junction cannot convert all photons into electron-hole pairs and only part of the solar spectrum range is covered. Therefore, double p-n junctions (see, e.g., U.S. Pat. No. 3,990,101 to Ettenberg, incorporated herein by reference) or more junctions (see, e.g., U.S. Pat. No. 7,217,882 B2 to Walukiewicz, incorporated herein by reference) are prepared on top of each other with few band gaps to cover a broader spectrum. A narrower band gap structure is placed on the bottom, then on top of it is prepared a structure with bigger band gap and the biggest band gap structure is prepared on top. Usually, triple-junction solar cells are used (see, e.g., U.S. Pat. No. 7,553,691 B2 Fatemi, incorporated herein by reference). Drawbacks of hetero-junctions solar cells are degradation of the materials and expensive fabrication method that requires many different compounds and materials. A solar cell having nanoparticles emitter (see, e.g., U.S. Pat. No. 7,705,237 B2 to Swanson, incorporated herein by reference) when emitters are doped with Si nanoparticeles. A quantum confinement effect for nanoparticles is generated when the band gap of a nanoparticle becomes bigger with smaller size. However, there can be a problem of clustering of nanoparticles and degradation during exposure to solar radiation. Another problem with p-n junctions is that electrons and holes are recombined in response to solar radiation, which recombination causes loss of electrons and reduced efficiency.

Therefore, there exists a need to make electron generation more efficient while also reducing the size of solar cells and making them easily integratable with widespread circuit fabrication technologies, such as CMOS, to reduce cost.

### SUMMARY

According to an embodiment, a Microelectromechanical system (MEMS) solar cell device includes a substrate, a sensing membrane exposed to light radiation being spaced from the substrate, a collector electrode disposed between the substrate and the sensing membrane, and a cavity defined between the sensing membrane and the collector electrode. The collector electrode collects charge carriers generated by light radiation on the sensing membrane within the cavity. A solar module or panel may be provided including a plurality of the cells arranged in an array on a substrate.

According to some of the more detailed features of the present invention, the cavity comprises a vacuum gap dimensioned in the nanometer scale, for example less than about 500 nanometers. The cavity, which may have a circular or a rectangular shape or any other suitable shape, can comprises a transition medium made of a gaseous material. Furthermore, a ground electrode is insulated from the collector electrode to enable flow of the collected charge carriers to a circuit. The circuit can be an energy storage circuit, such as a battery. Alternatively, the circuit can comprises a circuit integrated with the MEMS device using well known circuit fabrication processes, such as CMOS.

According to other more detailed features of the present invention, a resonator is coupled to the collector electrode and to the sensing membrane. Under this arrangement, the resonator, e.g., a quartz crystal, generates a feedback signal that is applied to the sensing membrane to form standing waves in the sensing membrane to enhance charge carrier collection by the collector electrode. In one embodiment, a deformation of the sensing membrane to form the standing waves provides variation of a band gap to generate electron-hole pairs from photons of a predetermined spectral range. The resonator can output AC voltage or short pulses to the sensing membrane to form the standing waves that could, for example, define concentric rings. In an embodiment, the sensing membrane may define a Fresnel lens structure. In an embodiment, a light source could be focused on the solar cell of the invention using a variety of mirror or lens structures.

A solar panel according to the present invention comprises a plurality of cells arranged in an array. Each cell comprises the MEMS solar cell devices described above.

Further features and advantages, as well as the structure and operation of various embodiments of the invention, are described in detail below with reference to the accompanying drawings.

### BRIEF DESCRIPTION OF THE DRAWINGS

The foregoing and other features and advantages of the invention will be apparent from the following, more particular description of some example embodiments of the invention, as illustrated in the accompanying drawings. Unless otherwise indicated, the accompanying drawing figures are not to scale. Several embodiments of the invention will be described with respect to the following drawings, in which like reference numerals represent like features throughout the figures, and in which:

FIG. 1 depicts a top schematic view of a MEMS solar cell array device according to an embodiment of the invention;

FIG. 2 schematically depicts a side cross-sectional view of a single cell of the solar cell array device of FIG. 1 taken along line FIG. 2-FIG. 2 and including circuitry for collecting electric charge, transferring electric charge, and applying a feedback signal to a sensing membrane of the cell;

FIG. 3 schematically depicts a side cross-sectional view of the MEMS solar cell array of FIG. 1 taken along line FIG. 3-FIG. 3;

FIG. 4 schematically depicts a side cross-sectional view of two adjacent cells of the MEMS solar cell array device of FIGS. 1-3 according to an embodiment of the invention;

FIG. 5 depicts a top schematic view of a MEMS solar cell array device having cavities of a substantially circular cross-section according to an embodiment of the invention;

FIGS. 6a-6c depicts three effective energy states during operation of the device of FIG. 1 according to an embodiment of the invention, wherein FIG. 6a depicts a cavity with no charge where effective electric potentials are equal on both sides of the cavity, FIG. 6b depicts a cavity filled with charge carriers generated by incident light or radiation, and FIG. 6c depicts a charge pulse transferring, wherein electric potentials establish the effective voltage;

FIG. 6d is an illustrative graph depicting charge flow vs. time, wherein after the state shown in FIG. 6c, the device returns to the state shown in FIG. 6a and the process repeats;

FIG. 7 depicts periodic charge flow pulses at resonance in the MEMS solar cell array device of FIGS. 1-5;

FIGS. 8a-8e depict the distribution function vs. energy of electrons for different times separated by a time step zit in a simulation, including electron-phonon interaction and electron-hole recombination;

FIG. 9 depicts the distribution function energy shift vs. time of the simulation of FIGS. 8a-8e, in which the steps mean quantization of the energy structure;

FIGS. 10a and 10b depict a maximum of the distribution function peak line (PL) vs. time and demonstrates decays for different transition probabilities; and

FIG. 11 schematically depicts a side cross-sectional view of a MEMS solar cell device having multiple cavities defining vacuum band gaps according to an embodiment of the invention.

### DETAILED DESCRIPTION

Some embodiments of the invention are discussed in detail below. In describing embodiments, specific terminology is employed for the sake of clarity. However, the invention is not intended to be limited to the specific terminology so selected. A person skilled in the relevant art will recognize that other equivalent components can be employed and other methods developed without departing from the broad concepts of the invention. All references cited herein are incorporated by reference as if each had been individually incorporated.

In its broadest sense, the present invention uses MEMS technology to covert solar radiation into solar energy. While conventional solar cells use solid state p-n junctions, embodiments of the present invention use a nano-scale “vacuum” or a nano-gap for generating electrical charge in response to solar radiation, which prevents recombination of electrons with holes reducing loss of electrons, and thus increasing efficiency.

Some embodiments of the current invention are directed to Microelectromechanical systems (MEMS) and nanoelectromechanical systems (NEMS). The MEMS and NEMS according to some embodiments of the current invention are applied to photonics energy and solar cells. Methods of fabricating MEMS and NEMS devices according to some embodiments of the current invention allow the fabrication of structures having nano-gaps which are significantly smaller than 1 micrometer and can be as small as a few nanometers in size, or even less than 1 nm (e.g., 0.5 nm). (In the remainder of this description, we often refer to MEMS devices, but that should be interpreted as including NEMS devices.) In addition, methods of producing devices according to some embodiments of the current invention allow to simplify fabrication of MEMS devices by avoiding encapsulation or other protection procedures such as sealing, etc. In addition, methods of production according to some embodiments of the current invention can also be used for encapsulation of devices. The fabrication methods according to some embodiments of the current invention can be used to make planar waveguides for light transmission. In addition, fabrication methods according to some embodiments of the current invention allow for the fabrication of vacuum gaps that do not need special sealing or protection against ambient atmosphere. For example, fabrication methods according to some embodiments of the current invention allow for fabrication of gaps inside the material and therefore, the gap automatically provides a vacuum relative to the surrounding environment.

The term vacuum as used here is intended to have a broad meaning to include partial vacuums as well as substantially complete vacuums, as long as the gas pressure within the gap is less than that of the surrounding environment. Nonetheless, in some cases, the vacuum can also be a high vacuum so that there is little easily discernable gas in the gap. An embodiment of the current invention provides a method of fabricating ultrathin gaps that can have a size of few nanometers, for example. We call this gap a nano-gap. According to some aspects of the current invention, the nano-gap can be formed when two or more specially chosen materials chemically react with each other to form a final material with higher density than the initial materials. Accordingly, the higher density will result in smaller volume. If these materials are placed between two solid structures, then the chemical reaction will lead to shrinking the volume occupied by the inner material. As a result, the difference between the initial volume and the final volume will release an empty space that will form the gap. The greater the difference between the densities of initial components and the density of the final material, the larger the volume that can be released. In addition to chemical reaction, a diffusion process can take place. One example of the method for fabricating nano-gaps is described in the U.S. patent application Ser. No. 12/961,079, filed on Dec. 6, 2010 and titled “Electromechanical Systems, Waveguides And Methods Of Production”, which is hereby incorporated by reference in its entirety.

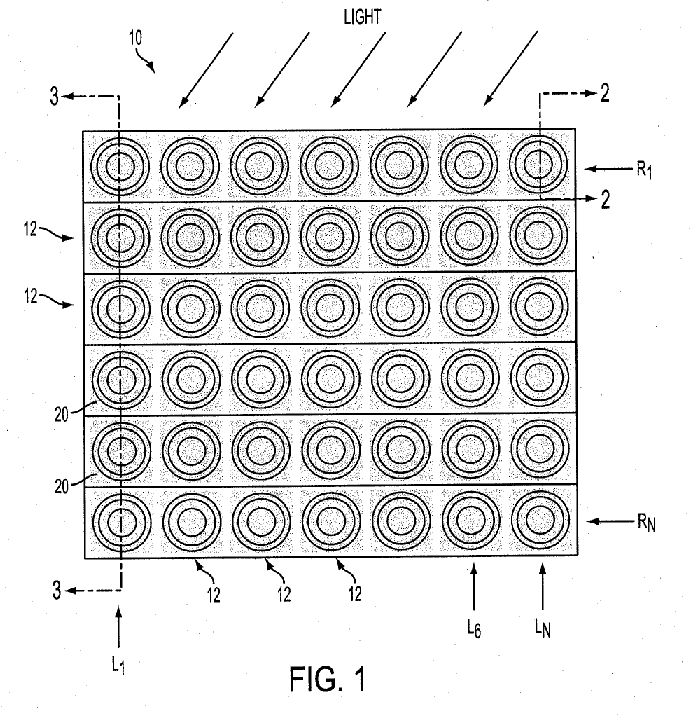

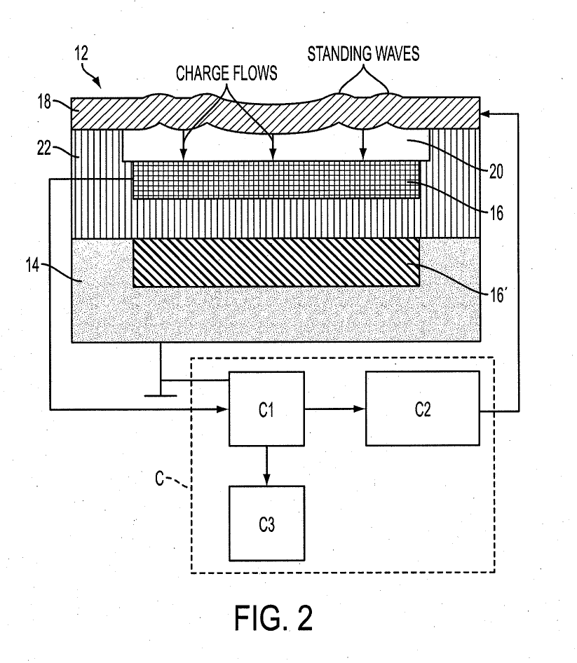

FIG. 1 depicts a top schematic view of a MEMS solar cell array device 10 according to an embodiment of the invention. The array 10 includes a plurality of cells 12 arranged in rows (R₁-R_{N}) and columns (L₁-L_{N}), each cell 12 comprising a MEMS solar cell device described in further detail below with reference to FIGS. 2-4. The array 10 is configured to generate power in response to light radiation such as, for example, solar radiation. The array 10 shown in FIG. 1 schematically depicts a solar module having forty-two cells 12 in six rows (R₁-R₆) and seven columns (L₁-L₇), although arrays with much greater quantities of cells are possible (e.g., orders of magnitude greater such as, for example, hundreds, thousands, or millions of cells).

FIG. 2 schematically depicts a side cross-sectional view of a single MEMS solar cell 12 of the solar cell array device 10 of FIG. 1 taken along line FIG. 2-FIG. 2 and including circuitry C for collecting electric charge, transferring electric charge, and applying a feedback signal to the cell 12. Each MEMS solar cell device 12 includes a substrate 14, an electrode 16, a sensing membrane 18, a cavity 20, and circuitry C. The substrate 14 has a smooth surface and can be made of different materials such as, for example, crystalline or amorphous silicon. The electrode may be made of, for example but not limited to, copper. As shown in the embodiment depicted in FIG. 2, the sensing membrane 18 may be a film layer of suitable material such as, for example but not limited to, a metal or another material compatible with deep vacuum gap materials, for example, Ti, Cu, Ag, TiN, or a combination. The sensing membrane 18 is spaced from the substrate 14 and the electrode 16 is disposed between the substrate 14 and the sensing membrane 18. The cavity 20 is defined by (between) the sensing membrane 18 and the electrode 16. The circuitry C includes a resonator C2 which is coupled to the electrode 16 and to the sensing membrane 18. When the sensing membrane 18 is exposed to incident light or radiation such as, for example, solar radiation, charge carriers are generated in the cavity 20 by the photovoltaic effect which are in turn collected by the electrode 16 and transmitted to the circuitry C. The resonator C2 is arranged to apply an AC voltage or short pulses to the sensing membrane 18 whereby resulting resonances at the cavity 20 form standing waves in the sensing membrane 18 to focus radiation within the cavity 20 and enhance charge carrier generation therein.

As shown in the embodiment depicted in FIG. 2, the electrode 16 may include first and second electrodes 16, 16′ separated by an insulation layer formed from a resistive material 22 such as, for example but not limited to, SiO₂ or another suitable material that isolates the electrodes 16, 16′ from each other. The resistive material 22 extends between the substrate 14 and the sensing membrane 18 and supports the sensing membrane 18. The resistive material 22 forms the side wall(s) of the cavity 20 and, in the solar cell array 10, defines a reinforcement grid or partition structure separating the respective cavities 12 from one another. The first electrode 16 is a collector electrode positioned adjacent to and defining a bottom surface of the cavity 20. The second electrode 16′, which is electrically insulated form the first electrode 16 by the resistive material 22, is a ground electrode positioned on or in the substrate 14 and coupled to ground. The electrodes 16, 16′ may be made as strip lines to minimize losses.

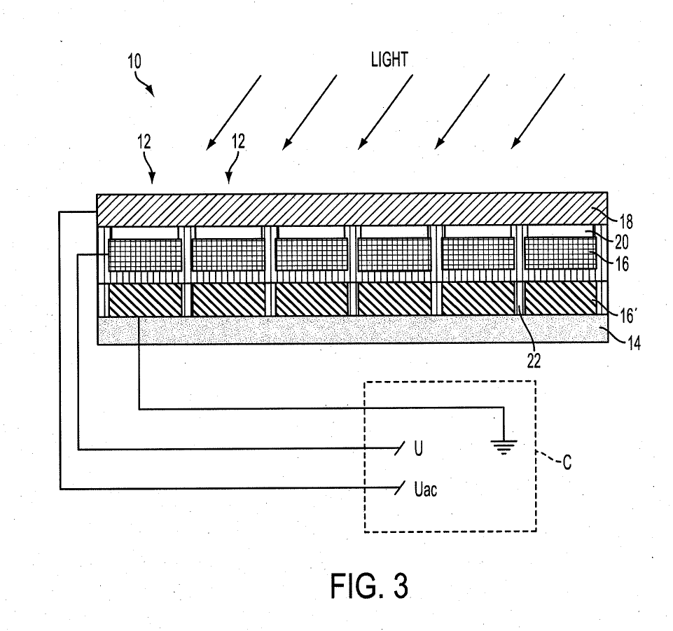

FIG. 3 schematically depicts a side cross-sectional view of a column L₁ of the MEMS solar cell array 10 of FIG. 1 taken along line FIG. 3-FIG. 3. Each MEMS solar cell device 12 in column L₁ includes the substrate 14, electrode 16, and sensing membrane 18. The respective cavities 20 are created between the collector electrode 16 and the sensing membrane 18. The resistive material 22 forms the side wall(s) of the cavities 20 and, in the solar cell array 10, defines a reinforcement grid or partition structure separating the respective cavities 12 from one another. The resistive material 22 also forms an isolation layer between the collector electrode 16 and the ground electrode 16′. The collector and ground electrodes 16, 16′ are connected to circuitry C.

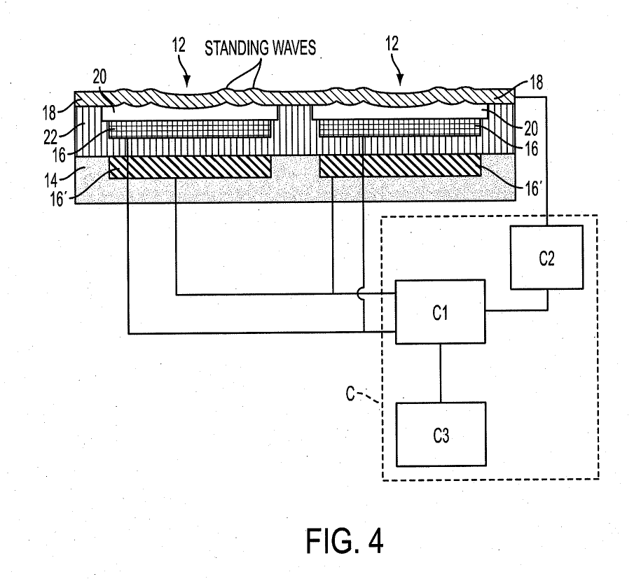

FIG. 4 schematically depicts a side cross-sectional view of two adjacent cells 12 of the MEMS solar cell array device 10 of FIGS. 1-3. As shown in the embodiments depicted in FIGS. 2-4, the cavity 20 is formed of a gap in which the top surface is formed by a surface of the sensing membrane 18, the bottom surface is formed by the collector electrode 16 and the side wall(s) of the cavity 20 are formed by the resistive material 22 supporting the sensing membrane 18. In one embodiment, the MEMS solar cell 12 will sense different photons because the cavity 20 has a variable gap width and, accordingly, a variety of effective band gap values. The cavity 20 covers a broad spectrum of light including ultraviolet, visible, and infrared. The cavity 20 can have a vacuum inside or a transition medium such as, for example, a gas. The cavities 20 can be nano-gaps of, for example, less than about 500 nm and fabricated in the resistive material 22 using, for example but not limited to, deep vacuum gap technology developed by ScanNanoTek and described, for example, in U.S. patent application Ser. No. 12/961,079, filed Dec. 6, 2010, entitled “Electromechanical Systems, Waveguides And Methods Of Production,” the entirety of which is hereby incorporated by reference. Larger vacuum gaps can provide conversion of X-rays for photon energies >100 eV and Gamma rays for photon energies >100 keV into electron-hole pairs. To cover this spectrum range, significantly larger gaps and larger oscillation amplitudes are required.

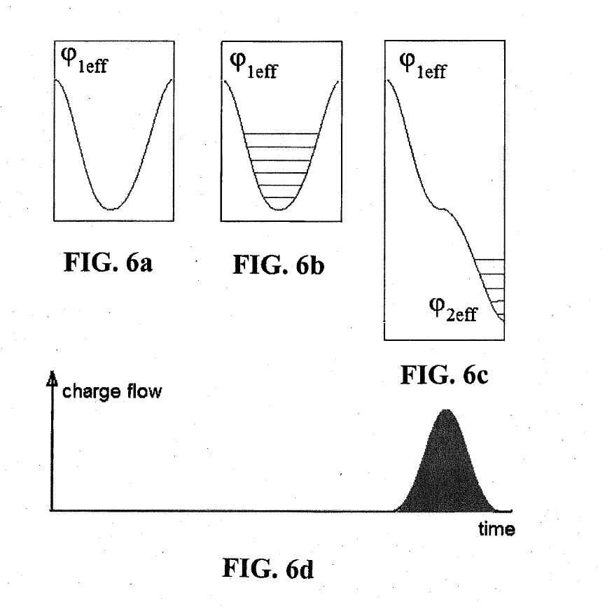

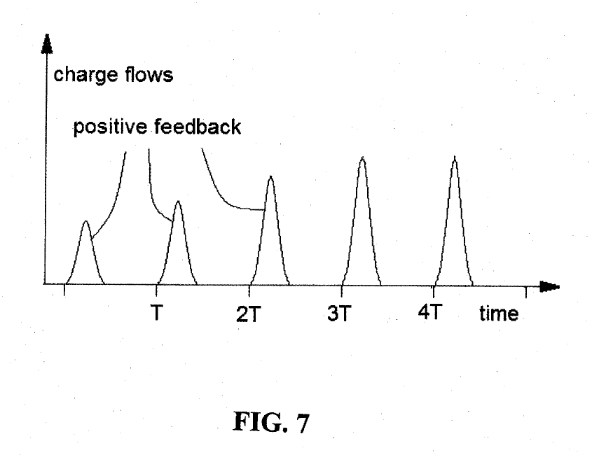

As shown in FIG. 4, the circuitry C includes collector circuitry C1 which is configured to receive the transferred charge and output two signals, one to a resonator C2 and another to integration circuitry C3. The resonator C2 provides an AC voltage or short pulses to the sensing membrane 18, which may be made of, for example but not limited to, a metal, a semiconductor, an alloy, or a combination thereof. The resonator C2 can be, for example but not limited to, a quartz crystal or another resonator. The integration circuitry C3 may be configured for transferring the electrical charge to a device to be powered (not shown), a power grid, or to a power storage device(s) such as, for example, a battery. In response to the AC voltage or short pulse output from resonator C2, the sensing membrane 18 has multiple local resonances at the cavities 20. The resonances can result in formation of standing mechanical waves in the sensing membrane 18 in the regions of the cavities 20 as schematically shown in FIGS. 1, 2, and 4. The sensing membrane 18 can interact with radiation, for example, with solar radiation, which radiation or photons generate charge carriers in the cavities 20. When a summation charge generated in the cavity 20 is large enough, then a charge pulse flows through the device, for example when the generated standing waves produce maximum deformation of the sensing membrane 18. This results in a current flow in accordance with formula I=dQ/dt, where I is current, Q is electrical charge and t is time. The charge flow pulse is formed from multichannel charge flows. The variable electrical current can be transformed into DC current by the electric circuitry C, for example, by integration circuitry C3. FIG. 6d is an illustrative graph depicting charge flow vs. time, wherein after the state shown in FIG. 6c, the device returns to the state shown in FIG. 6a and the cycle repeats. As such, a deformation of the sensing membrane 18 generates an electrical charge pulse that triggers a cycle of charge carrier collection by the collector electrode 16.

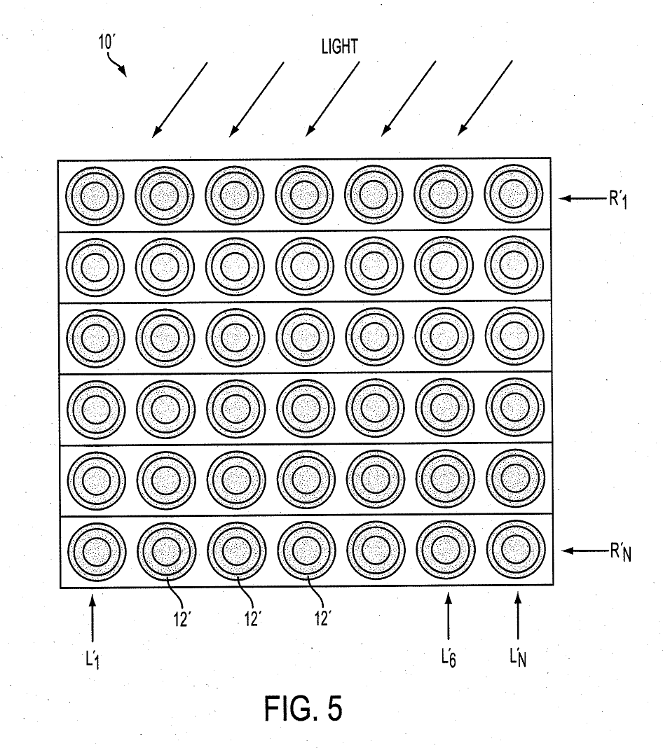

FIG. 5 depicts a top schematic view of the MEMS solar cell array device 10′ having cells 12′ with cavities 20′ of a substantially circular cross-section according to an embodiment of the invention. The cavities 20 shown in FIG. 1 have a rectangular or square cross-sectional configuration defined by the shape of the recess in the resistive material 22, although the cavities 20 are not limited to this shape and other shapes are possible such as, for example but not limited to, circular (FIG. 5), curvilinear, oval, elliptical, multi-sided, etc. FIGS. 1 and 5 show the standing waves in the form of concentric rings generated by local resonances in the top sensing membrane 18.

The MEMS solar cell array device 10 is designed so that local oscillations have resonance/resonances that are most sensitive to the maximum of the energy peak of radiation. Particularly, thickness of the sensing membrane 18, composition of the sensing membrane 18, and size and shape of the cavities 20 can be adjusted to achieve the peak position. The oscillations at resonance can form standing waves which can focus light into the device 12, particularly, in the cavity 20, and enhancing generation of charge carriers. The standing waves can have, for example, a Fresnel rings (lens) structure. Fermi surface with centers in the cavities 20 can be formed during interaction of the device 10 with light enhancing generation of charge carriers. The charge carriers may be collected by the collector electrode 16 and further transformed into electrostatic charge or mechanical force or momentum via circuitry C.

The dynamics of charge transfer follow the uncertainty principle. For example, when the sensing membrane 18 moves inside the cavity 20 then the position of an electron is better defined, but the momentum of the electron is less defined in accordance with the equation ΔxΔp≧b/2. These local oscillations produce an electrical displacement and associated local electrical potential. The produced pulses of the electric charge from the collector electrode 16 are collected by the collector circuitry C1. The cells 12 can provide power of P=I²V²/I₀V₀. A focused solar light can be exposed to the cells 12. Focusing can be performed by, for example, a lens, a mirror or other means.

The cavity 20 is described by a vacuum band gap function F(E)

$$F ( E ) = 1 - \frac{1}{cosh ( γ \frac{2 E}{Eg} )} ,$$

Where E is energy, E_{g} (x,y,z,t) is width of the vacuum band gap associated with the vacuum cavity 20, x and y are coordinates in a horizontal plane, z is a gap size at this position; t being time, the local band gap value depends on value z, and γ is a coefficient related with geometry and material (including vacuum) of the cavity 20. Standing waves of sensing membrane 18 provide gap variations of the cavity 20 and associated variations of the band gap over the MEMS device. When the cell 12 is designed for average band gap of E₀=2 eV, then the variation of the vacuum gap in the range of zmax/zmin=10 provides the band gap energy range from about Eₘᵢₙ=E₀(zₘᵢₙ/z₀)=0.6 eV to Eₘₐₓ=E₀(zₘₐₓ/z₀)=6 eV. This covers most of the solar spectrum. Electrons of the sensing membrane are distributed in accordance with the free electron gas model. The vacuum cavity 20 prevents recombination of electrons with holes reducing loss of electrons.

FIGS. 6a-6c depicts three effective energy states during operation of the MEMS solar cell array device 10 of FIGS. 1-5 according to an embodiment of the invention, wherein FIG. 6a depicts a cavity with no charge where effective electric potentials are equal on both sides of the cavity, FIG. 6b depicts a cavity filled with charge carriers generated by incident light or radiation, and FIG. 6c depicts a charge pulse transferring, wherein electric potentials establish the effective voltage. FIG. 6d is an illustrative graph depicting charge flow vs. time, wherein after the state shown in FIG. 6c, the device returns to the state shown in FIG. 6a and the process repeats

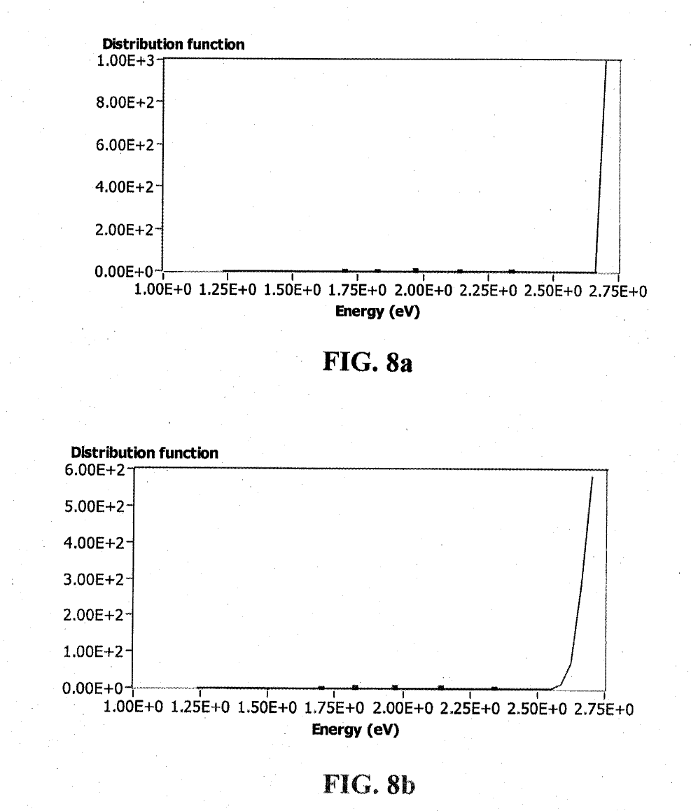

FIG. 7 depicts the periodic charge flow pulses over time generated at resonance in the MEMS solar cell array device 10 of FIGS. 1-5 according to an embodiment of the invention. Over time, a higher efficiency of the device 10 is achieved when amplitude of the pulses increases reaches a maximum value due to the above-described creation of the standing waves in sensing membrane 18 over cavity 20.

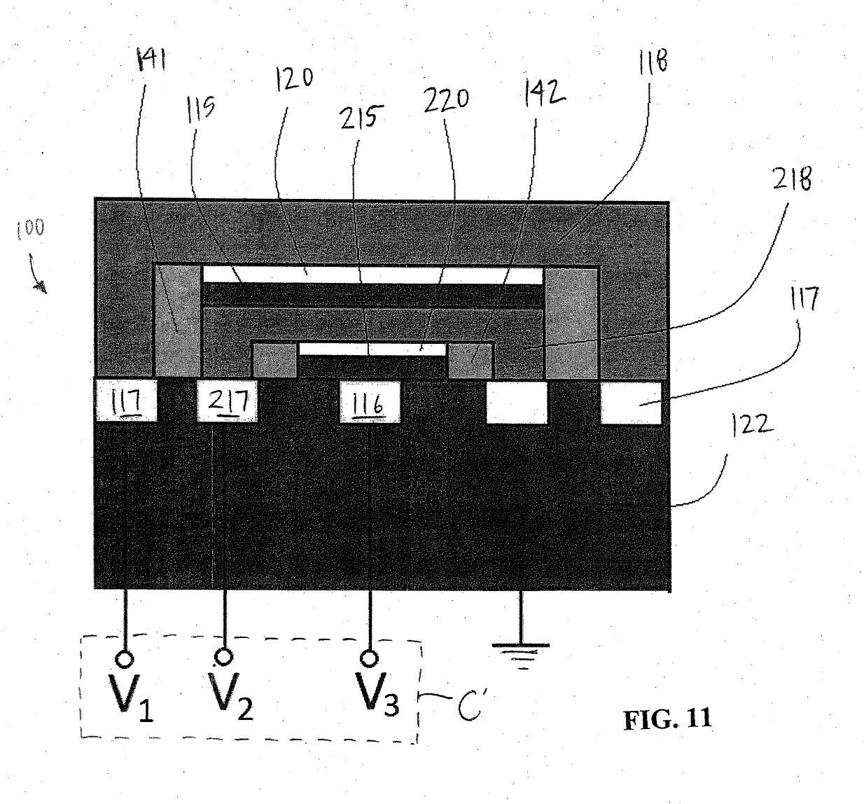

FIG. 11 schematically depicts a side cross-sectional view of a MEMS solar cell device 100 having multiple cavities 25, 26 defining multiple vacuum band gaps according to another embodiment of the invention. The cell 100 includes a MEMS double-gap solar cell device. The cell 100 includes a first sensing membrane 118 spaced from a first buffer layer 115 to define a first cavity 120. The cell 100 includes a second sensing membrane 218 below the first buffer layer 115 and spaced from a second buffer layer 215 to define a second cavity 220. The cell 100 includes a resistive material 122 of a suitable material such as, for example, SiO₂, supporting and separating the afore-mentioned structures of the cell 100. The first and second cavities 12, 220 define individual vacuum gaps. The resistive material 122 may include insulation regions 141, 142 defining side walls of the first and second cavities 120, 220, and supporting sensing membranes 118, 218, respectively. The circuitry C′ is coupled to the sensing membranes 118, 218 via contacts 117, 217. When the sensing membranes 118, 218 are exposed to light radiation such as, for example, solar radiation, charge carriers are generated in the cavities 120, 220 by the photovoltaic effect which are in turn collected by the electrode 116 and transmitted to the circuitry C′. As in the embodiments described above, the circuitry C′ is arranged to apply an AC voltage or short pulses to one or both of the sensing membranes 118, 218 whereby resulting resonances at the cavities 120, 220 form standing waves in the sensing membranes 118, 218 to focus radiation within the cavities 120, 220 and enhance charge carrier generation therein. The cell 100 may also include a base substrate (not shown). Although FIG. 11 depicts a double-gap MEMS solar cell device, embodiments are envisioned with more than two cavities.

### Simulation Model

A resonant cavity with a capacity of N electronic states is considered. N equations of motion with electron-phonon interaction and electron-hole recombination are solved for short time steps. The result of the time step tᵢ becomes the initial condition for next time step tᵢ₊₁. A computer simulation can model dynamics of electrons and correlate these properties with the mechanical model. Assumptions of the model include the following:
1. The number of electrons in a cavity is limited to a certain maximum number.
2. The electrons can freely move inside the cavity.
3. Electrical current is directly correlated with mechanical energy of electrons
4. The energy structure comprises two energy bands and a vacuum band gap. For modeling movement of electrons, a system of energy levels is considered. The excited electron moves inside the cavity and its energy is constant until the electron interacts with a phonon. It is assumed that the probability of this interaction is higher at the bounding surface of the cavity. During this interaction the electron loses a portion of energy equaling the phonon's energy. The electron can travel through the cavity to the collector electrode or it can continue its movement inside the cavity but with less energy.
5. The lifetime of an electron at a particular energy state is equal to the traveling time between two collisions with phonons. The lower the electron energy the longer lifetime.
6. To model the electron transport it is assemed that generated electrons have the same energy and start their movement inside the cavity with a given probability of electron-phonon interaction. After each interaction the electron's energy is decreased by phonon energy and the electron moves to one energy step lower.
7. The simulation program calculates energy distribution of electrons. The energy structure consists of a system of equidistant energy levels.

The dynamic model can be described in terms of kinetic energy of a system of N electrons moving inside the cavity. At initial time all electrons are excited and have the same kinetic energy. The electron-phonon interaction can be written as

$${\sum }_{i = 1}^{N} {mv}_{i} \frac{d {v}_{i}}{d t } = {E}_{phon} {\sum }_{i = 1}^{N} {σ}_{phon , i} + {\sum }_{i = 1}^{N} {σ}_{p h , i} {E}_{p h , i} . \qquad ( 1 )$$

Here σ_{phon,i} is a probability of electron-phonon interaction of ith electron during the time Δt and σ_{ph,I} is a probability of electron to pass through the cavity. Each electron is described by a wave function Ψᵢ. The probability of electron-phonon interaction is related with electron velocity and size of the cavity given by

$${σ}_{phon , i} = \frac{{v}_{i} Δ t}{l + {v}_{i} Δ t} , \qquad ( 2 )$$

where l is the width of the cavity.

The kinetic energy Eij of an electron after interaction with phonon is

$$\frac{{m}_{i} {v}_{i}^{2}}{2} = \frac{{{m}_{i} ( {v}_{i} - δ {v}_{i} )}^{2}}{2} + {E}_{phon} = {E}_{i , j} + {E}_{phon} \qquad ( 3 )$$

During electron-phonon interaction the total initial kinetic energy decreases so that the total energy

$$\sum \frac{{m}_{i} {v}_{i 0}^{2}}{2} = {\sum }_{i = 1}^{N} \frac{{m}_{i} {v}_{ij}^{2}}{2} + {\sum }_{j = 1}^{J} {σ}_{phon} \sum {E}_{phon} + {\sum }_{j = 1}^{J} {σ}_{p h} \sum {E}_{p h} \qquad ( 5 )$$

at time t=JΔt.

The motion of N electrons is simulated where electron-phonon interaction and electron-hole recombination are included. The simulation program calculates energies of electrons for different times separated by time step. The time step zit is short enough so that during one time step an electron has only one electron-phonon interaction. At the beginning of the process all electrons have the same energy of 2.7 eV. There are 40 energy states inside the energy region 1.2 eV to 2.7 eV. The total number of electrons is assumed to be 1000. This value is chosen for convenience and may be normalized. The transition probability is 0.9995 per 1 ns. The transition probability is a probability with which an electron remains in the system after electron-phonon interaction during one time step. It is assumed all electrons have equal energies when the initial distribution function is δ-function.

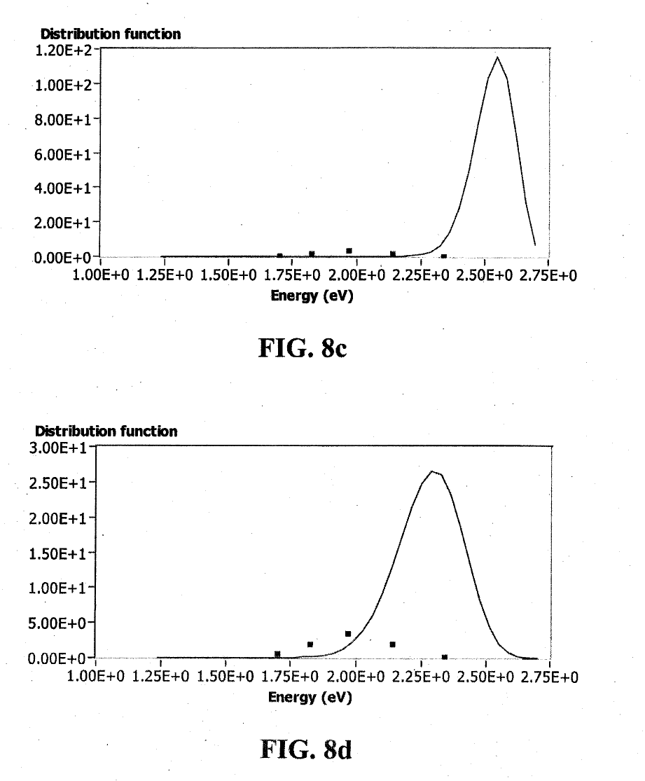

FIGS. 8a-8e depict the distribution function vs. energy of electrons for different times separated by a time step Δt in a simulation, including electron-phonon interaction and electron-hole recombination. In FIG. 8a, the initial distribution function is δ-function. The number of moving electrons is 1000. In FIG. 8b. the distribution function is shown after 100 ns. The number of moving electrons is 951. In FIG. 8c, the distribution function is shown after 1 μs. The number of moving electrons is 605. In FIG. 8d, the distribution function is shown after 3 μs. The number of moving electrons is 223. In FIG. 8e, the distribution function is shown after 6.5 μs. The number of moving electrons is 39.

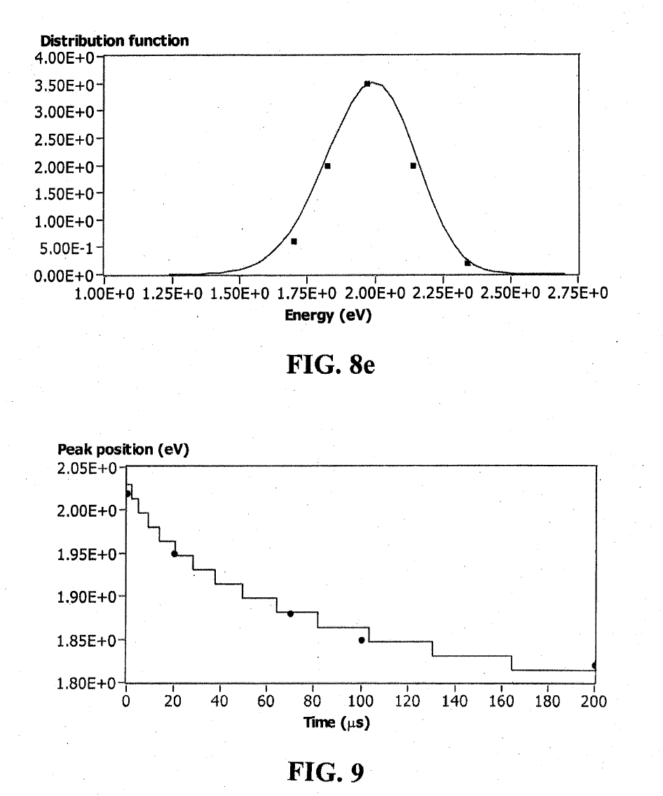

FIG. 9 depicts the distribution function energy shift vs. time of the simulation of FIGS. 8a-8e, in which the steps mean quantization of the energy structure. The symbols show the shift of the peak position. The transition probability is 0.9993 for one time step of 10 ns.

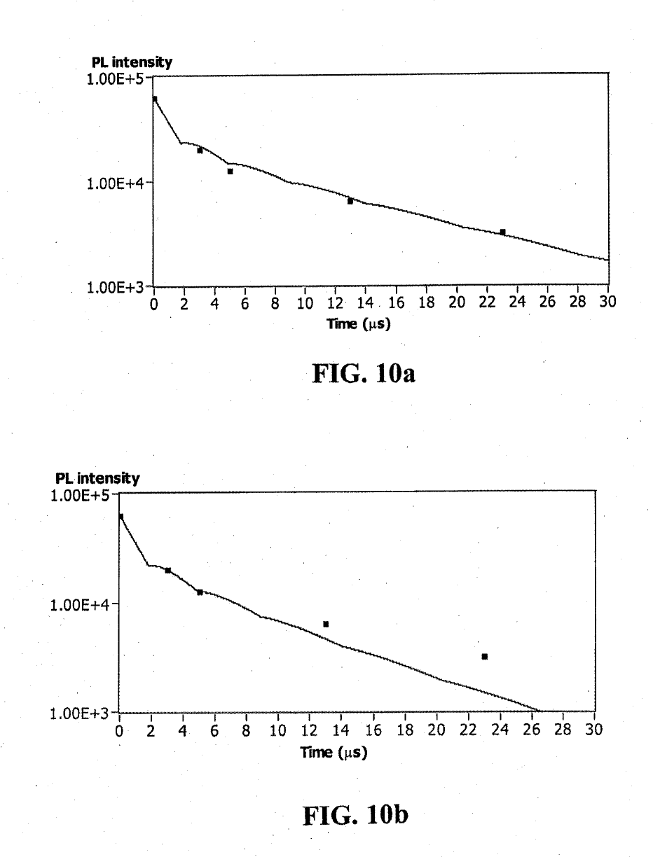

FIGS. 10a and 10b depict a maximum of the distribution function peak line (PL) vs. time and demonstrates decays for different transition probabilities. This decay is dependent on transition probability. In FIG. 10b, the transition probability is 0.9990.

The peak lines obtained during simulation are compared with the normal distribution functions (NDF) given by the equation

$$f ( E , t ) = \frac{1}{\sqrt{2 π} σ ( t )} exp ( - \frac{1}{2} {( \frac{E - μ ( t )}{σ ( t )} )}^{2} )$$

where E is electron energy, μ(t) is a chemical potential at moment t and σ is standard deviation, σ=0.03 eV, coefficient of linear increase is 1.0005 per transition. Value 1/0.0005=0.9995 is the transition probability used in the simulation. The rate used for process of electron-phonon interaction is given by the formula r=a e^{-t/τ}, where r is a rate, the amplitude a=4.82E−3, −1/τ=−1.77E−2 or τ=56.5 ns. The standard deviation can be attributed then to the phonon energy spectrum given by

σₙ=σₙ₋₁/p,

where σ₀=Eₚₕ₀ is an initial phonon energy, p is transmission probability. This is a geometrical progression and this expression can be rewritten as

σₙ=Eₚₕ₀/pⁿ

A linear increase of the lifetime is introduced with energy state number. This simple approximation can be changed to the formula

$${τ}_{i} = l \sqrt{\frac{m}{2 ( {E}_{i} - {E}_{0} )}} ,$$

where m is electron mass, (Ei−Eo) electron energy and l free path. The travelling distance l is equal to the width of the cavity in first approximation.

While various embodiments of the present invention have been described above, it should be understood that they have been presented by way of example only, and not limitation. Thus, the breadth and scope of the present invention should not be limited by any of the above-described embodiments, but should instead be defined only in accordance with the following claims and their equivalents.

1. A microelectromechanical system (MEMS) solar cell device, comprising:
a substrate;
a sensing membrane exposed to light radiation being spaced from the substrate,
a collector electrode disposed between the substrate and the sensing membrane;
a cavity defined between the sensing membrane and the collector electrode, wherein the collector electrode collects charge carriers generated by light radiation on the sensing membrane within the cavity.

2. The MEMS solar cell device according to claim 1, wherein charge carriers are generated in the cavity in response to at least one of visible light waves, ultraviolet light waves, and infrared light waves.

3. The MEMS solar cell device according to claim 1, wherein the cavity comprises a vacuum gap dimensioned in the nanometer scale.

4. The MEMS solar cell device according to claim 3, wherein the vacuum gap is less than about 500 nanometers.

5. The MEMS solar cell device according to claim 1, further comprising a ground electrode that is insulated from the collector electrode to enable flow of the charge carriers to a circuit.

6. The MEMS solar cell device according to claim 5, wherein the collector electrode and ground electrode comprise strip lines.

7. The MEMS solar cell device according to claim 1, the cavity comprises a transition medium made of a gas.

8. The MEMS solar cell device according to claim 1, wherein the cavity comprises one of a circular or a rectangular shape.

9. The MEMS solar cell device according to claim 1, wherein the sensing membrane comprises a metal, a semiconductor, an alloy, or a combination thereof.

10. The MEMS solar cell device according to claim 5, wherein the circuit comprises an energy storage circuit.

11. The MEMS solar cell device according to claim 5, wherein the circuit comprises a circuit that is integrated with the MEMS solar cell device using a CMOS circuit fabrcation process.

12. The MEMS solar cell device according to claim 1, further comprising a resonator coupled to the collector electrode and to the sensing membrane, the resonator generating a feedback signal applied to the sensing membrane to form standing waves in the sensing membrane.

13. The MEMS solar cell device according to claim 12, wherein the resonator outputs AC voltage or short pulses to the sensing membrane to form the standing waves.

14. The MEMS solar cell device according to claim 12, wherein the resonator comprises a quartz crystal.

15. The MEMS solar cell device according to claim 12, wherein the standing waves define concentric rings.

16. The MEMS solar cell device according to claim 12, wherein the standing waves define a Fresnel lens structure.

17. The MEMS solar cell device according to claim 12, wherein a deformation of the sensing membrane to form the standing waves provides variation of a band gap to generate electron-hole pairs from photons of a predetermined spectral range.

18. The MEMS solar cell device according to claim 1, wherein the substrate comprises silicon.

19. The MEMS solar cell device according to claim 1, wherein the cavity comprises a multi-gap structure.

20. A solar panel comprising:
a plurality of cells arranged in an array on a substrate, wherein each cell comprises:
a sensing membrane exposed to light radiation being spaced from the substrate;
a collector electrode disposed between the substrate and the sensing membrane; and
a cavity defined between the sensing membrane and the collector electrode, wherein the collector electrode collects charge carriers generated by light radiation on the sensing membrane within the cavity.
